(19) United States
(12) Patent Application Publication
(10) Pub. No.: US 2021/0302830 A1
(43) Pub. Date: Sep. 30, 2021

(54) METHOD OF MANUFACTURING TEMPLATE, TEMPLATE, AND METHOD OF MANUFACTURING SEMICONDUCTOR DEVICE

(71) Applicant: Kioxia Corporation, Tokyo (JP)

(72) Inventors: Kosuke TAKAI, Yokohama Kanagawa (JP); Kazuhiro TAKAHATA, Yokohama Kanagawa (JP); Akihiko ANDO, Machida Tokyo (JP)

(73) Assignee: Kioxia Corporation, Tokyo (JP)

(21) Appl. No.: 17/016,546

(22) Filed: Sep. 10, 2020

(30) Foreign Application Priority Data
Mar. 24, 2020 (JP) 2020-052033

(51) Int. Cl. G03F 7/00; B29C 33/38

(52) U.S. Cl. CPC G03F 7/0002; H01L 21/027; B29C 33/3842

(57) ABSTRACT

A method of manufacturing a template, includes: covering a part of a first region of a substrate; processing another part of the first region to form a first pattern including a protrusion; covering the first region; and processing at least part of a second region of the substrate to form a second pattern including a depression.

### CROSS-REFERENCE TO RELATED APPLICATION

This application is based upon and claims the benefit of priority from Japanese Patent Application No. 2020-052033, filed on Mar. 24, 2020; the entire contents of which are incorporated herein by reference.

### FIELD

Embodiments of the present invention relate to a method of manufacturing a template, a template, and a method of manufacturing a semiconductor device.

### BACKGROUND

A known method of manufacturing a semiconductor device include forming a fine pattern using nanoimprint lithography (NIL).

### BRIEF DESCRIPTION OF THE DRAWINGS

FIG. 1 is an explanatory flowchart of an example of a method of manufacturing a template of a first embodiment.

FIG. 2 is an explanatory schematic perspective view of a structure example of the template.

FIG. 3 is an explanatory schematic sectional view of the structure example of the template.

FIG. 4 is an explanatory schematic upper view of a layout example on a plane MS.

FIG. 5 is an explanatory schematic upper view of an example of a first mask forming step S1-1.

FIG. 6 is an explanatory schematic sectional view of the example of the first mask forming step S1-1.

FIG. 7 is an explanatory schematic upper view of an example of a first substrate processing step S1-2.

FIG. 8 is an explanatory schematic sectional view of the example of the first substrate processing step S1-2.

FIG. 9 is an explanatory schematic upper view of an example of a second mask forming step S1-3.

FIG. 10 is an explanatory schematic sectional view of the example of the second mask forming step S1-3.

FIG. 11 is an explanatory schematic upper view of an example of a second substrate processing step S1-4.

FIG. 12 is an explanatory schematic sectional view of the example of the second substrate processing step S1-4.

FIG. 13 is an explanatory flowchart of an example of an optical layer forming step S2.

FIG. 14 is an explanatory schematic sectional view of an example of an optical layer deposition step S2-1.

FIG. 15 is an explanatory schematic sectional view of an example of a mask forming step S2-2.

FIG. 16 is an explanatory schematic sectional view of an example of a mask processing step S2-3.

FIG. 17 is an explanatory schematic sectional view of an example of an optical layer processing step S2-4.

FIG. 18 is an explanatory schematic perspective view of a shape example of a first pattern and a second pattern.

FIG. 19 is an explanatory schematic perspective view of a shape example of the first pattern and the second pattern.

FIG. 20 is an explanatory schematic upper view of another example of the first mask forming step S1-1.

FIG. 21 is an explanatory schematic sectional view of the other example of the first mask forming step S1-1.

FIG. 22 is an explanatory schematic upper view of another example of the first substrate processing step S1-2.

FIG. 23 is an explanatory schematic sectional view of the other example of the first substrate processing step S1-2.

FIG. 24 is an explanatory schematic upper view of another example of the second mask forming step S1-3.

FIG. 25 is an explanatory schematic sectional view of the other example of the second mask forming step S1-3.

FIG. 26 is an explanatory schematic upper view of another example of the second substrate processing step S1-4.

FIG. 27 is an explanatory schematic sectional view of the other example of the second substrate processing step S1-4.

FIG. 28 is an explanatory schematic sectional view of another example of the optical layer forming step S2.

FIG. 29 is an explanatory schematic perspective view of a structure example of the template.

FIG. 30 is an explanatory schematic upper view of still another example of the second mask forming step S1-3.

FIG. 31 is an explanatory schematic sectional view of the still another example of the second mask forming step S1-3.

FIG. 32 is an explanatory schematic upper view of still another example of the second substrate processing step S1-4.

FIG. 33 is an explanatory schematic sectional view of the still another example of the second substrate processing step S1-4.

FIG. 34 is an explanatory schematic sectional view of still another example of the optical layer forming step S2.

FIG. 35 is an explanatory schematic perspective view of a structure example of the template.

FIG. 36 is an explanatory schematic upper view of still another example of the first mask forming step S1-1.

FIG. 37 is an explanatory schematic sectional view of the still another example of the first mask forming step S1-1.

FIG. 38 is an explanatory schematic upper view of still another example of the first substrate processing step S1-2.

FIG. 39 is an explanatory schematic sectional view of the still another example of the first substrate processing step S1-2.

FIG. 40 is an explanatory flowchart of yet another example of the second mask forming step S1-3.

FIG. 41 is an explanatory schematic sectional view of an example of a hard mask forming step S1-3-1.

FIG. 42 is an explanatory schematic sectional view of an example of a resist mask forming step S1-3-2.

FIG. 43 is an explanatory schematic sectional view of an example of a resist mask processing step S1-3-3.

FIG. 44 is an explanatory schematic sectional view of an example of a hard mask processing step S1-3-4.

FIG. 45 is an explanatory flowchart of an example of a method of manufacturing a semiconductor device using NIL.

FIG. 46 is an explanatory schematic sectional view of an example of an alignment step S-A.

FIG. 47 is an explanatory schematic sectional view of an example of a pattern transfer step S-B.

FIG. 48 is an explanatory schematic sectional view of an example of an object processing step S-C.

FIG. 49 is an explanatory schematic sectional view of an example of a deposition step S-D.

### DETAILED DESCRIPTION

A method of manufacturing a template, includes: covering a part of a first region of a substrate; processing another part of the first region to form a first pattern including a protrusion; covering the first region; and processing at least part of a second region of the substrate to form a second pattern including a depression.

Embodiments will be hereinafter described with reference to the drawings. In the drawings, the relation of thickness and planer dimension of each constituent element, a thickness ratio among the constituent elements, and so on can be different from actual ones. Further, in the embodiments, substantially the same constituent elements are denoted by the same reference signs, and a description thereof will be omitted when appropriate.

### First Embodiment

(Example of a Method of Manufacturing a Template)

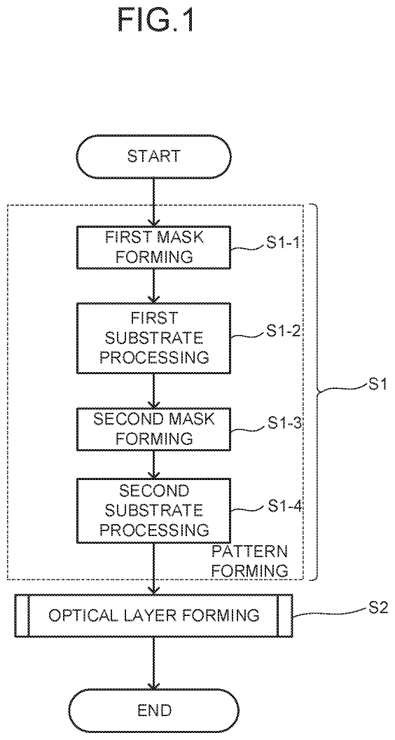

FIG. 1 is an explanatory flowchart of an example of a method of manufacturing a template of a first embodiment. The example of the method of manufacturing a template of the first embodiment includes a pattern forming step S1 and an optical layer forming step S2 as illustrated in FIG. 1.

a method of forming a pattern using NIL includes pressing a template onto an imprint material layer such as an ultraviolet curing resin on an object, irradiating the imprint material layer with light to cure the imprint material layer, and then transferring the pattern to the imprint material layer. Before pressing the template, the method includes alignment for aligning the template and the object. The alignment enables the transfer of the pattern to the imprint material layer with high positional accuracy.

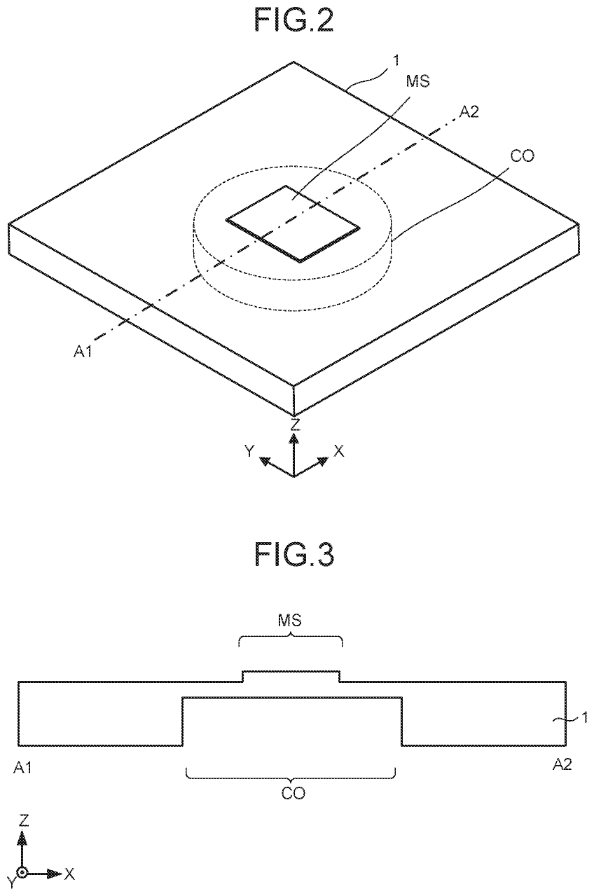

FIG. 2 is an explanatory schematic perspective view of a structure example of the template. FIG. 3 is an explanatory schematic sectional view of the structure example of the template and illustrates part of an X-Z cross-section of a substrate 1 including an X axis and a Z axis orthogonal to the X axis and a Y axis. FIG. 3 illustrates a cross-section along the line A1-A2 in FIG. 2.

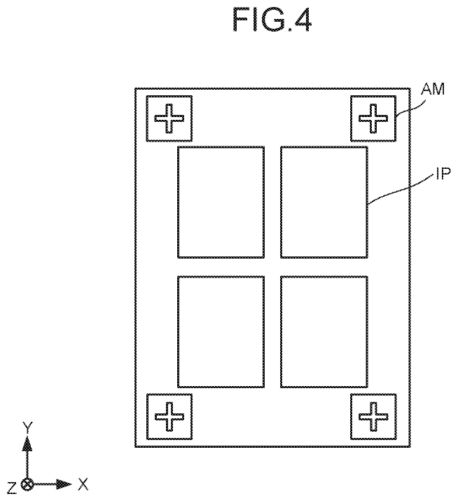

As illustrated in FIGS. 2 and 3, the template has the substrate 1 including a plane MS called messa and an opening CO. FIG. 4 is an explanatory schematic upper view of a layout example on the plane MS and illustrates part of an X-Y plane of the substrate 1. The plane MS includes alignment mark patterns AM and imprint patterns IP. The alignment mark patterns AM are masks for alignment (alignment marks). The imprint patterns IP are patterns which are to be transferred by the method using NIL. The numbers, positions, and shapes of the alignment mark patterns AM and the imprint patterns IP are not limited. An example of the method including the imprint patterns IP each including a plurality of pillars and the alignment mark patterns AM each including a cross-shaped groove will be described as an example. The imprint patterns IP and the alignment mark patterns AM is not limited to the above and can include line-and-space patterns.

[Pattern Forming Step S1]

As illustrated in FIG. 1, the pattern forming step S1 includes a first mask forming step S1-1, a first substrate processing step S1-2, a second mask forming step S1-3, and a second substrate processing step S1-4.

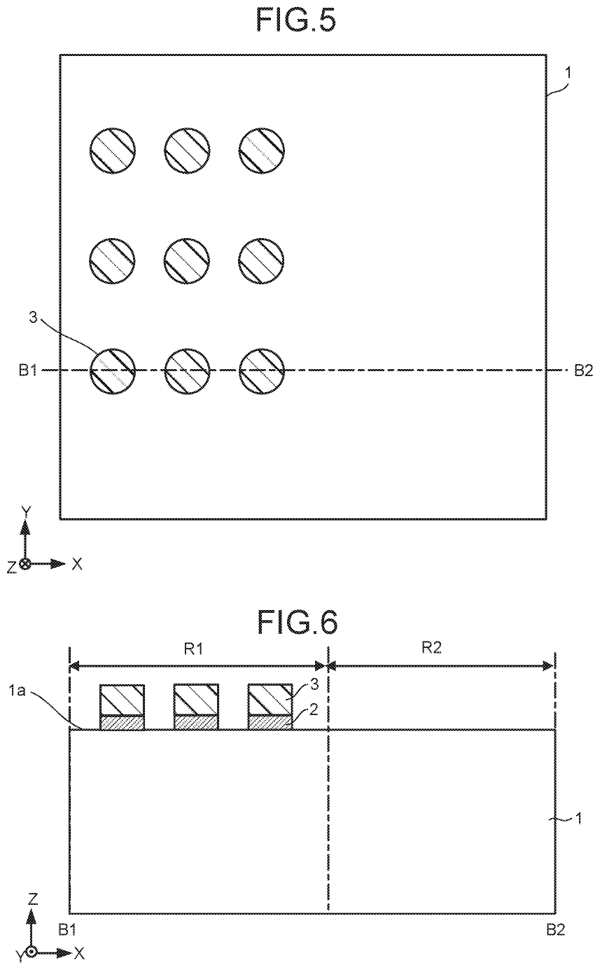

FIG. 5 is an explanatory schematic upper view of an example of the first mask forming step S1-1 and illustrates part of the X-Y plane of the substrate 1. FIG. 6 is an explanatory schematic sectional view of the example of the first mask forming step S1-1 and illustrates part of an X-Z cross-section of the substrate 1 along the line B1-B2 in FIG. 5. The exemplified method is described using regions R1 and R2 schematically illustrated with the substrate 1, the region R1 being where to form the imprint pattern IP, and the region R2 being where to form the alignment mark pattern AM. The regions R1 and R2 in FIGS. 5 and 6 face a surface 1a.

The first mask forming step S1-1 forms a hard mask layer 2 on the surface 1a of the substrate 1, forms a resist mask layer 3 including a pattern on the hard mask layer 2, and processes the hard mask layer 2 using the resist mask layer 3, to form a first mask including the hard mask layer 2 and the resist mask layer 3 and covering some parts of the region R1 as illustrated in FIGS. 5 and 6.

Examples of the substrate 1 contain quartz. The substrate 1 preferably transmits light.

The hard mask layer 2 has a function as a hard mask for processing the substrate 1. The hard mask layer 2 can contain chromium (Cr). The hard mask layer 2 can be processed by dry etching. Examples of the dry etching for processing the hard mask include inductively coupled plasma (ICP)-reactive ion etching (RIE) using a mixed gas of a chlorine (Cl₂) gas and an oxygen (O₂) gas.

The resist mask layer 3 has a function as a resist mask for processing the hard mask layer 2. Examples of the resist mask layer 3 are formed by processing a film containing photoresist with electron beam (EB) exposure. The processing is not limited to the above method. Examples of the mask layer 3 can be formed using a method of forming a pattern using NIL.

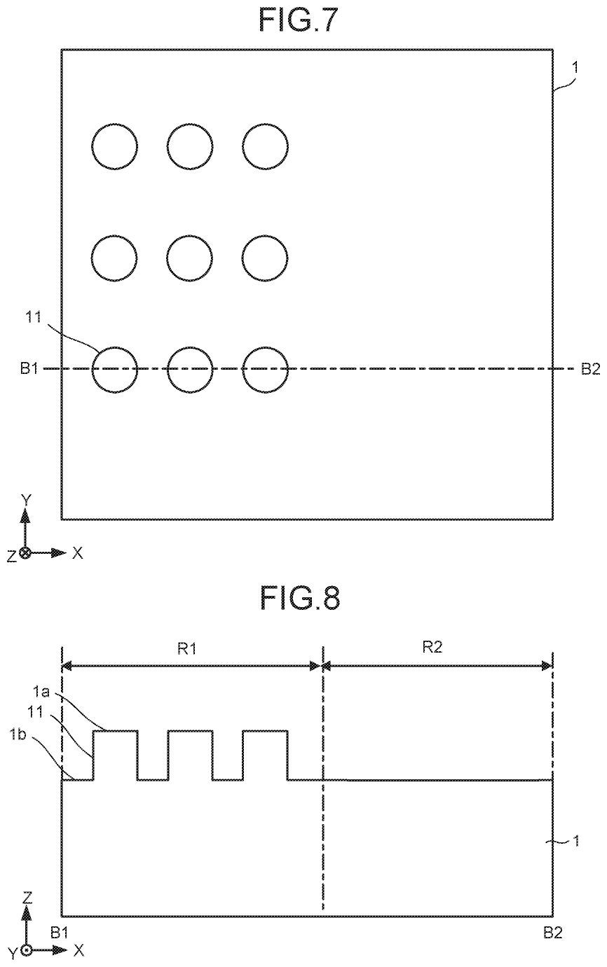

FIG. 7 is an explanatory schematic upper view of an example of the first substrate processing step S1-2 and illustrates part of the X-Y plane of the substrate 1. FIG. 8 is an explanatory schematic sectional view of the example of the first substrate processing step S1-2 and illustrates part of the X-Z cross-section of the substrate 1 along the line B1-B2 in FIG. 7.

The first substrate processing step S1-2 processes the other part of the region R1 and at least part of the region R2 using the first mask, to form a surface 1b lower than the surface 1a and the imprint pattern IP including protrusions 11 protruding more than the surface 1b to the surface 1a. After the first substrate processing step S1-2, the first mask is removed.

The other part of the region R1 can be processed by being partly removed along the thickness direction of the substrate 1 from the surface 1a using anisotropic etching such as dry etching. Examples of the dry etching for processing the substrate 1 include inductively coupled plasma (ICP)-reactive ion etching (RIE) using a trifluoromethane (CHF₃) gas.

Each of the protrusions 11 can have an upper surface including a part of the surface 1a. The protrusions 11 can be made of the remainder of the region R1.

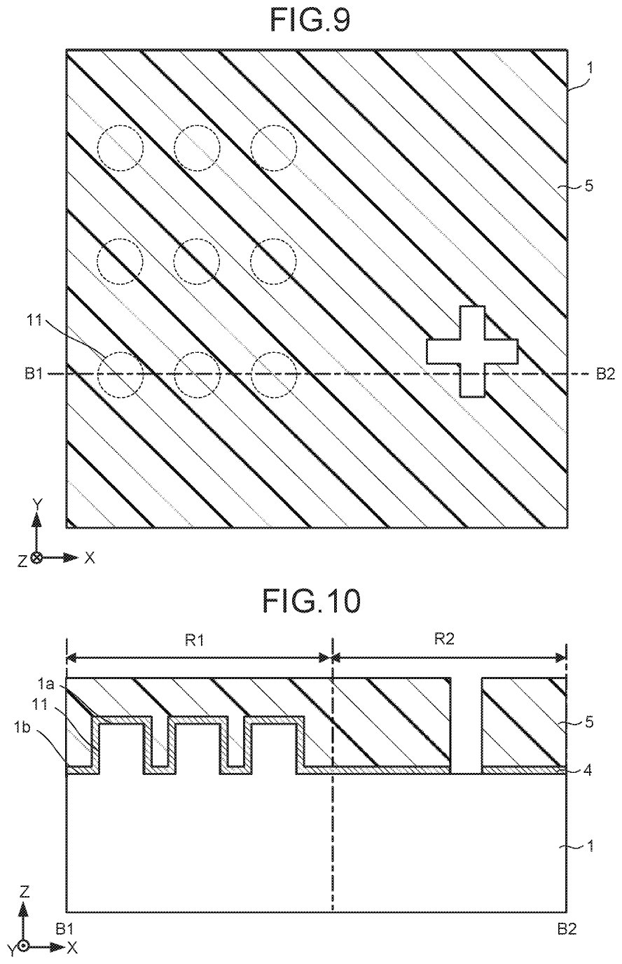

FIG. 9 is an explanatory schematic upper view of an example of the second mask forming step S1-3 and illustrates part of the X-Y plane of the substrate 1. FIG. 10 is an explanatory schematic sectional view of the example of the second mask forming step S1-3 and illustrates part of the X-Z cross-section of the substrate 1 along the line B1-B2 in FIG. 9.

The second mask forming step S1-3 forms a hard mask layer 4 covering the regions R1 and R2, forms a resist mask layer 5 including a pattern on the hard mask layer 4, and then processes the hard mask layer 4 using the resist mask layer 5, to form a second mask including the hard mask layer 4 and the resist mask layer 5 and covering the region R1 and also covering part of the region R2 as illustrated in FIG. 9 and FIG. 10.

The hard mask layer 4 has a function as a hard mask for processing the substrate 1. Examples of the hard mask layer 4 contain chromium (Cr). The hard mask layer 4 can be processed by dry etching.

The resist mask layer 5 has a function as a resist mask for processing the hard mask layer 4. The resist mask layer 5 can be formed by processing a film containing photoresist using electron beam (EB) exposure. The processing is not limited to the above method. The resist mask layer 5 can be formed using a method of forming a pattern using NIL.

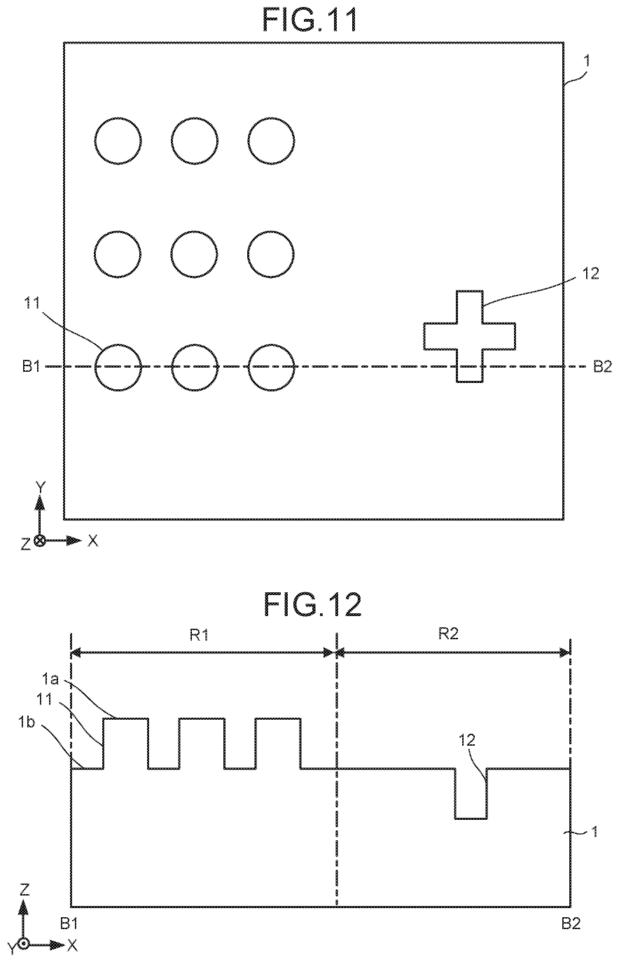

FIG. 11 is an explanatory schematic upper view of an example of the second substrate processing step S1-4 and illustrates part of the X-Y plane of the substrate 1. FIG. 12 is an explanatory schematic sectional view of the example of the second substrate processing step S1-4 and illustrates part of the X-Z cross-section of the substrate 1 along the line B1-B2 in FIG. 11.

The second substrate processing step S1-4 processes the other part of the region R2 using the second mask to form the alignment mark pattern AM including a depression 12 depressed more than the surface 1b to the surface 1a. After the second substrate processing step S1-4, the second mask is removed.

The other part of the region R2 can be processed by being partly removed along the thickness direction of the substrate 1 from the surface 1b by anisotropic etching such as dry etching.

[Optical Layer Forming Step S2]

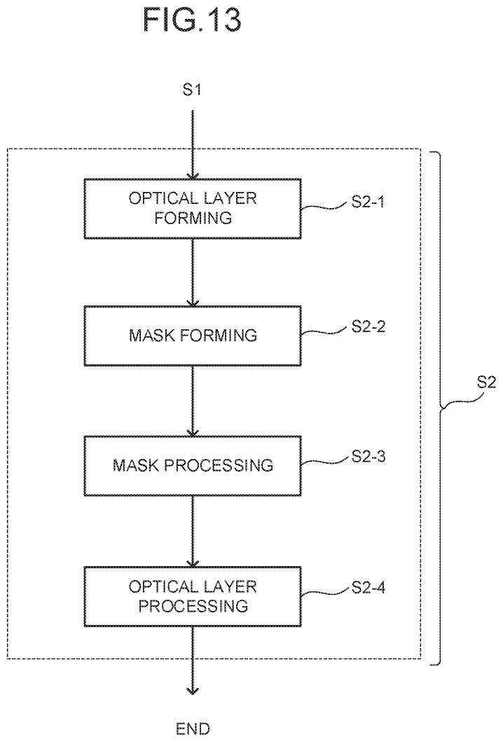

FIG. 13 is an explanatory flowchart of an example of the optical layer forming step S2. The example of the optical layer forming step S2 includes an optical layer deposition step S2-1, a mask forming step S2-2, a mask processing step S2-3, and an optical layer processing step S2-4.

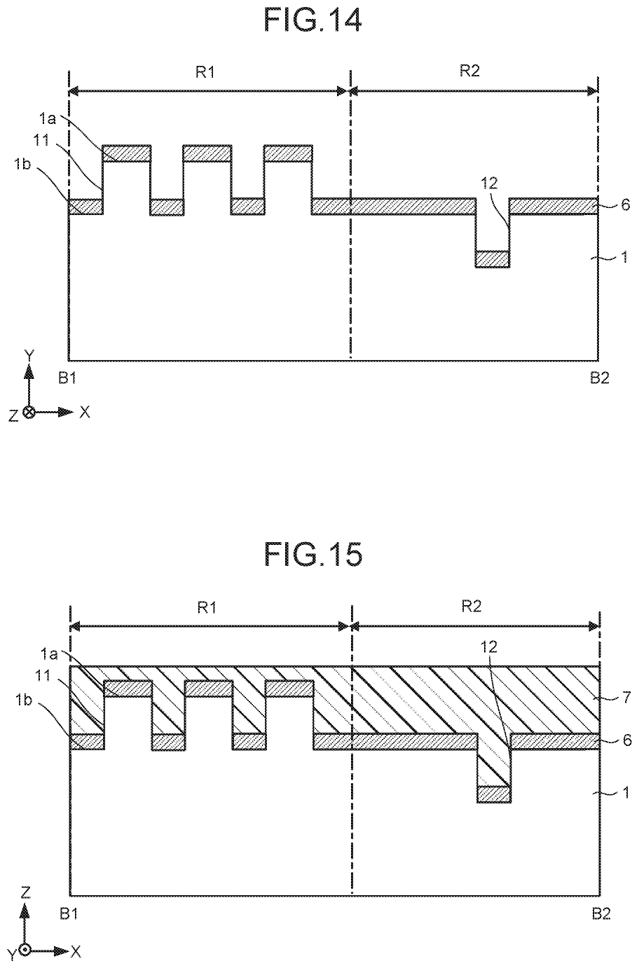

FIG. 14 is an explanatory schematic sectional view of an example of the optical layer deposition step S2-1 and illustrates part of the X-Z cross-section of the substrate 1 along the line B1-B2. The optical layer deposition step S2-1 deposits an optical layer 6 on the region R1 and the region R2.

The optical layer 6 has a refractive index different from the refractive index of the substrate 1. The optical layer 6 can contain at least one material selected from the group consisting of titanium, tantalum, chromium, tungsten, copper, silicon carbide, and silicon fluoride. The optical layer 6 can be formed by depositing a material usable for the optical layer 6 onto the substrate 1 by reactive sputtering.

FIG. 15 is an explanatory schematic sectional view of an example of the mask forming step S2-2 and illustrates part of the X-Z cross-section of the substrate 1 along the line B1-B2. The mask forming step S2-2 forms a resist mask layer 7 on the optical layer 6. The resist mask layer 7 can be formed by spin coating. Examples of the resist mask layer 7 does not have a pattern as illustrated in FIG. 15.

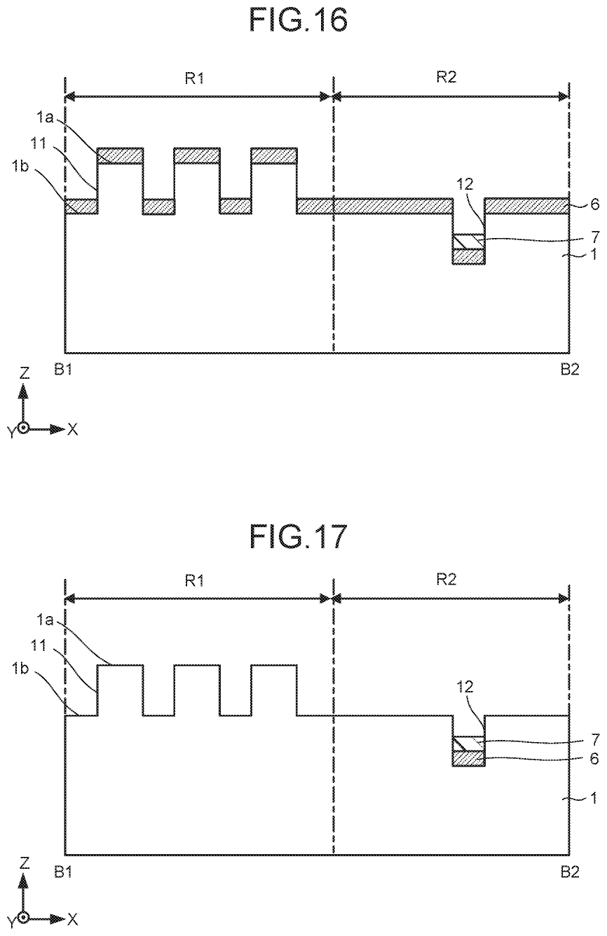

FIG. 16 is an explanatory schematic sectional view of an example of the mask processing step S2-3 and illustrates part of the X-Z cross-section of the substrate 1 along the line B1-B2. The mask processing step S2-3 processes the resist mask layer 7, to form a third mask covering only the other part of the region R2. The resist mask layer 7 is processed by being partly removed along the thickness direction of the resist mask layer 7 (direction substantially the same as the Z-axis direction) by anisotropic etching such as dry etching.

FIG. 17 is an explanatory schematic sectional view of an example of the optical layer processing step S2-4 and illustrates part of the X-Z cross-section of the substrate 1 along the line B1-B2. The optical layer processing step S2-4 processes the optical layer 6 using the third mask. After the optical layer processing step S2-4, the resist mask layer 7 is removed. The optical layer 6 can be processed by removing the exposed part of the optical layer 6 by dry etching. The remainder of the resist mask layer 7 can be removed along with the removal of the exposed part of the optical layer 6.

Through the above steps, it is possible to form the optical layer 6 in the depression 12. Providing the optical layer 6 makes it possible to make the depression 12 and the other region contrast with each other, enabling the easy detection of the alignment mark pattern AM using an optical detector. This can enhance the accuracy of the alignment between the template and the object.

As described above, the example of the method of manufacturing a template of the first embodiment processes the substrate in the plurality of processing steps, to form a first pattern including the protrusion and a second pattern including the depression. This can enhance the flexibility of the pattern shape. The method of manufacturing a template of the first embodiment can process a substrate having a first surface to form a second surface lower than the first surface, the first pattern including the protrusions protruding more than the second surface, and the second pattern including the depression depressed more than the second surface.

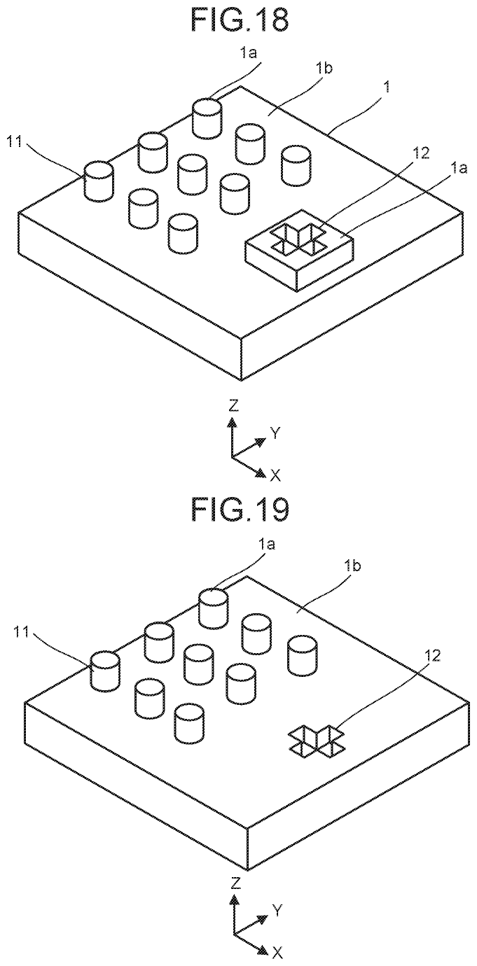

FIG. 18 and FIG. 19 are explanatory schematic perspective views of shape examples of the first pattern and the second pattern. FIG. 18 and FIG. 19 each schematically illustrate part of the substrate 1 having the surface 1a, the surface 1b, the imprint patterns IP each including the protrusions 11, and the alignment mark patterns AM each including the depression 12.

If the imprint pattern IP including the protrusions 11 and the alignment mark pattern AM including the depression 12 are formed in a single substrate processing step, since the depression 12 is provided to be depressed from the surface 1a, a region around the depression 12 protrudes to the same height as the upper surfaces of the protrusions 11 as illustrated in FIG. 18. When a pattern is transferred to the imprint material layer by NIL using a template including this alignment mark pattern AM, the region around the depression 12 forms an unnecessary depression in the imprint material layer. When the object is thereafter processed using the imprint material layer including the transferred pattern, an unnecessary depression is also formed in the object. Therefore, when embedded wiring can be formed in the object in a later semiconductor device manufacturing step, a metal layer can be formed also in the unnecessary depression, resulting in an unnecessary wiring capacitance, which can degrade the performance of the semiconductor device.

In contrast, the exemplified method of manufacturing a template of the first embodiment can depress the depression 12 more than the surface 1b without causing the region around the depression 12 to protrude more than the surface 1a as illustrated in FIG. 19. This can prevent the formation of the unnecessary depression in the imprint material layer formed by NIL. The depression 12 can be applied not only to the alignment mark pattern but also to part of the imprint pattern.

### Second Embodiment

An example of a method of manufacturing a template of a second embodiment includes a pattern forming step S1 and an optical layer forming step S2 similarly to the example of the method of manufacturing a template of the first embodiment. The second embodiment details configurations different from those of the first embodiment with omitting the description of configurations as same as those of the first embodiment.

[Pattern Forming Step S1]

The pattern forming step S1 includes a first mask forming step S1-1, a first substrate processing step S1-2, a second mask forming step S1-3, and a second substrate processing step S1-4 as in the first embodiment.

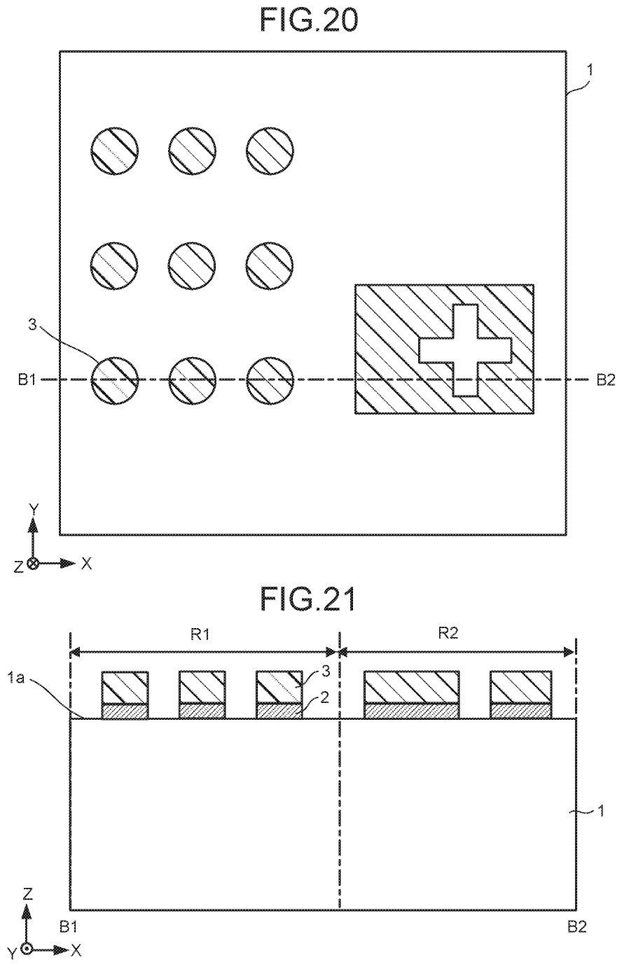

FIG. 20 is an explanatory schematic upper view of another example of the first mask forming step S1-1 and illustrates part of the X-Y plane of the substrate 1. FIG. 21 is an explanatory schematic sectional view of the other example of the first mask forming step S1-1 and illustrates part of the X-Z cross-section of the substrate 1 along the line B1-B2 in FIG. 20.

The first mask forming step S1-1 forms a hard mask layer 2 on the surface 1a of the substrate 1, forms a resist mask layer 3 with a pattern and on the hard mask layer 2, and processes the hard mask layer 2 using the resist mask layer 3, to form a first mask including the hard mask layer 2 and the resist mask layer 3 and covering some parts of the region R1 and part of the region R2 as illustrated in FIGS. 20 and 21. The other description of the other example of the first mask forming step S1-1 can appropriately refer the description of the example of the first mask forming step S1-1 of the first embodiment.

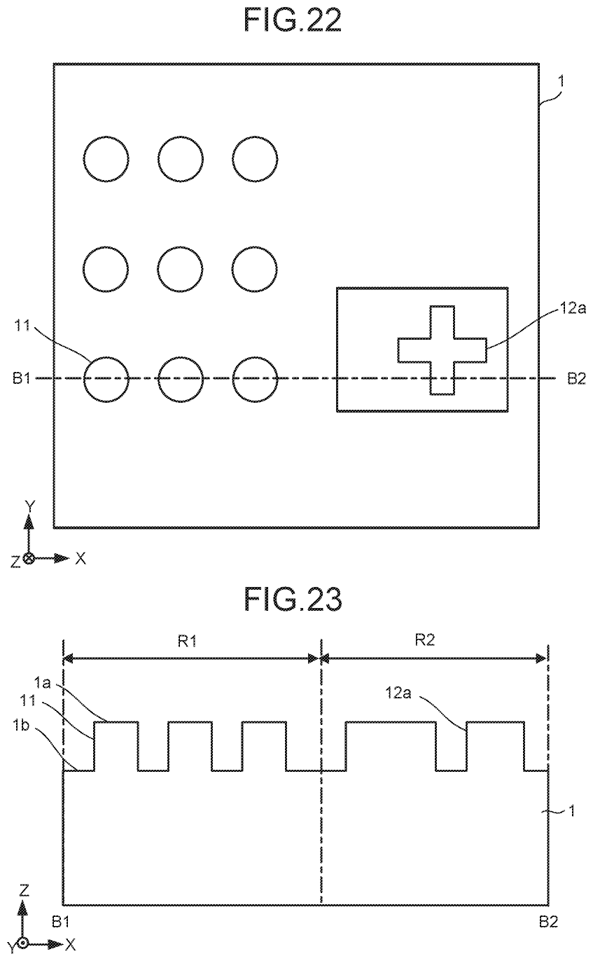

FIG. 22 is an explanatory schematic upper view of another example of the first substrate processing step S1-2 and illustrates part of the X-Y plane of the substrate 1. FIG. 23 is an explanatory schematic sectional view of the other example of the first substrate processing step S1-2 and illustrates part of the X-Z cross-section of the substrate 1 along the line B1-B2 in FIG. 22.

The first substrate processing step S1-2 processes the other part of the region R1 and the other part of the region R2 using the first mask, to form a pre-pattern including a groove 12a depressed from the surface 1a, with the surface 1b and the imprint pattern IP. The first mask is removed after the first substrate processing step S1-2.

The other part of the region R2 can be processed with the other part of the region R1 by being partly removed along the thickness direction of the substrate 1 from the surface 1a by anisotropic etching such as dry etching. The other description of the other example of the first substrate processing step S1-2 can appropriately refer the description of the example of the first substrate processing step S1-2 of the first embodiment.

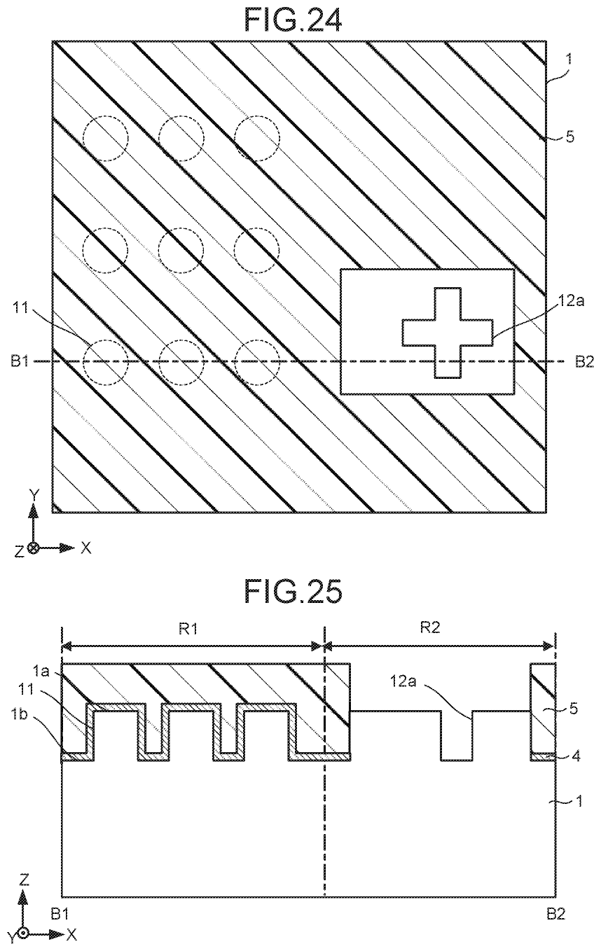

FIG. 24 is an explanatory schematic upper view of another example of the second mask forming step S1-3 and illustrates part of the X-Y plane of the substrate 1. FIG. 25 is an explanatory schematic sectional view of the other example of the second mask forming step S1-3 and illustrates part of the X-Z cross-section of the substrate 1 along the line B1-B2 in FIG. 24.

The second mask forming step S1-3 forms a hard mask layer 4 covering the region R1 and also covering the region R2, forms a resist mask layer 5 including a pattern on the hard mask layer 4, and processes the hard mask layer 4 using the resist mask layer 5, to form a second mask covering the region R1, exposing part of the region R2 and another part of the region R2, and covering still another part of the region R2 as illustrated in FIGS. 24 and 25. The other description of the other example of the second mask forming step S1-3 can appropriately refer the description of the example of the second mask forming step S1-3 of the first embodiment.

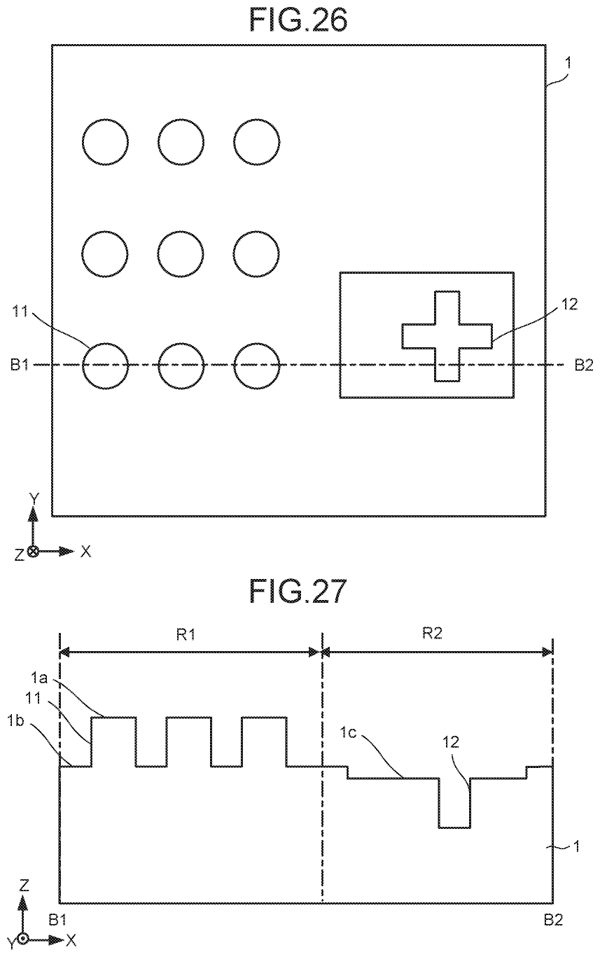

FIG. 26 is an explanatory schematic upper view of another example of the second substrate processing step S1-4 and illustrates part of the X-Y plane of the substrate 1. FIG. 27 is an explanatory schematic sectional view of the other example of the second substrate processing step S1-4 and illustrates part of the X-Z cross-section of the substrate 1 along the line B1-B2 in FIG. 26.

The second substrate processing step S1-4 further processes the part of the region R2 while maintaining the shape of the pre-pattern, using the second mask, to form a surface 1c lower than the surface 1b to the first surface 1a, and further processes the other part, of the region R2, which includes the groove 12a, to form the alignment mark pattern AM including the depression 12. After the second substrate processing step S1-4, the second mask is removed. The surface 1c can surround the depression 12. The other description of the other example of the second substrate processing step S1-4 can appropriately refer the description of the example of the second substrate processing step S1-4 of the first embodiment.

[Optical Layer Forming Step S2]

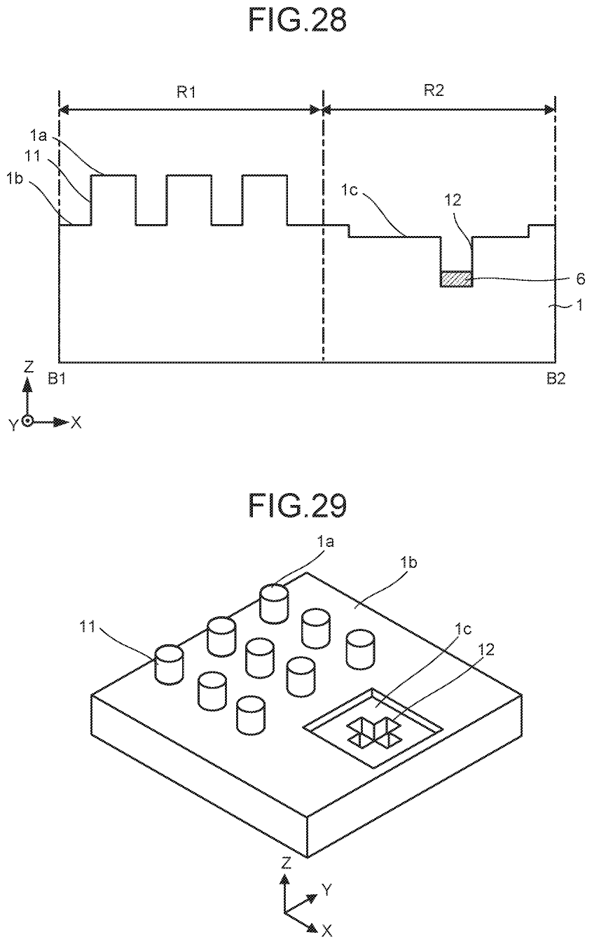

FIG. 28 is an explanatory schematic sectional view of another example of the optical layer forming step S2 and illustrates part of the X-Z cross-section of the substrate 1 along the line B1-B2. The optical layer forming step S2 forms the optical layer 6 in the depression 12 through the same steps as those of the example of the optical layer forming step S2 of the first embodiment. The other description of the other example of the optical layer forming step S2 can appropriately refer the description of the example of the optical layer forming step S2 of the first embodiment.

As described above, the example of the method of manufacturing a template of the second embodiment processes the substrate in the plurality of processing steps, to form a first pattern including the protrusions and a second pattern including the depression. This method can enhance the flexibility of the pattern shape. This method can process a substrate having a first surface to form a second surface lower than the first surface, the first pattern including the protrusions protruding more than the second surface, and the second pattern including the depression depressed more than the second surface.

FIG. 29 is an explanatory schematic perspective view of a structure example of the template. FIG. 29 schematically illustrates part of the substrate 1 having the surface 1a, the surface 1b, the surface 1c, the imprint patterns IP each including the protrusions 11, and the alignment mark patterns AM each including the depression 12.

The example of the method of manufacturing a template of the second embodiment can depress the depression 12 more than the surface 1c without causing the region around the depression 12 to protrude more than the surface 1a as illustrated in FIG. 29. This can prevent the formation of an unnecessary depression in the imprint material layer formed by NIL. The example of the method of manufacturing a template of the second embodiment also can form the pre-pattern with the imprint pattern IP, and then process the pre-pattern to form the alignment mark pattern AM. This reduces an error in the relative position of the imprint pattern IP and the alignment mark pattern AM.

The second embodiment can be appropriately combined with any of the other embodiments.

### Third Embodiment

An example of a method of manufacturing a template of a third embodiment includes a pattern forming step S1 and an optical layer forming step S2 similarly to the example of the method of manufacturing a template of the first embodiment. The third embodiment details configurations different from those of the first embodiment with omitting the description of configurations as same as those of the first embodiment.

[Pattern Forming Step S1]

The pattern forming step S1 includes a first mask forming step S1-1, a first substrate processing step S1-2, a second mask forming step S1-3, and a second substrate processing step S1-4 as in the first embodiment. The first mask forming step S1-1 and the first substrate processing step S1-2 are the same as the first mask forming step S1-1 and the first substrate processing step S1-2 of the second embodiment, and therefore a description thereof will be omitted here.

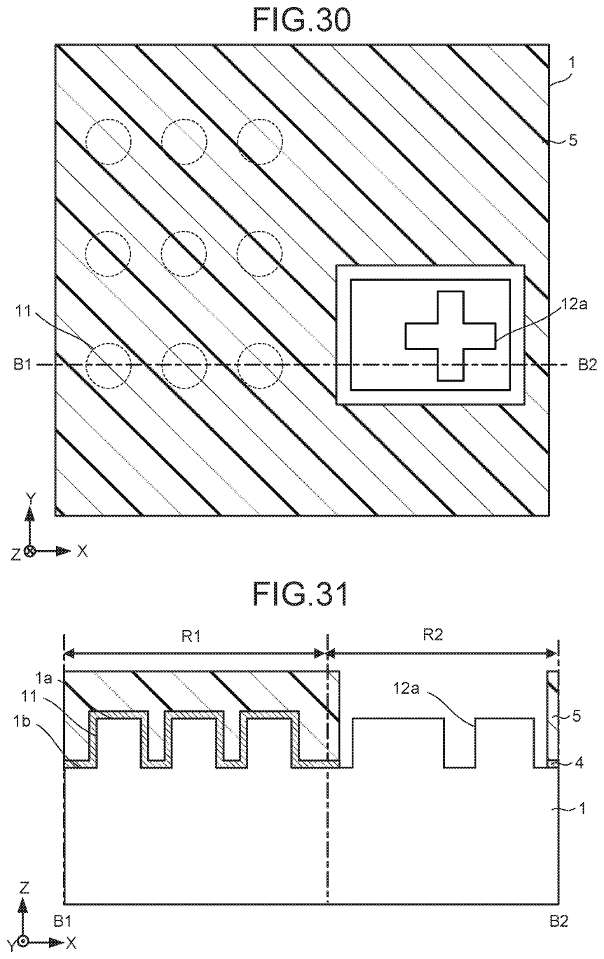

FIG. 30 is an explanatory schematic upper view of still another example of the second mask forming step S1-3 and illustrates part of the X-Y plane of the substrate 1. FIG. 31 is an explanatory schematic sectional view of the still another example of the second mask forming step S1-3 and illustrates part of the X-Z cross-section of the substrate 1 along the line B1-B2 in FIG. 30.

The second mask forming step S1-3 forms a hard mask layer 4 covering the region R1 and also covering the region R2, forms a resist mask layer 5 including a pattern on the hard mask layer 4, and processes the hard mask layer 4 using the resist mask layer 5, to form a second mask including the hard mask layer 4 and the resist mask layer 5, covering the region R1, exposing part of the region R2, another part of the region R2, and still another part of the region R2, and covering yet another part of the region R2 as illustrated in FIGS. 30 and 31. The yet another part of the region R2 is disposed between the other part of the region R2 and the region R1. The other description of the still another example of the second mask forming step S1-3 can appropriately refer the description of the example of the second mask forming step S1-3 of the first embodiment.

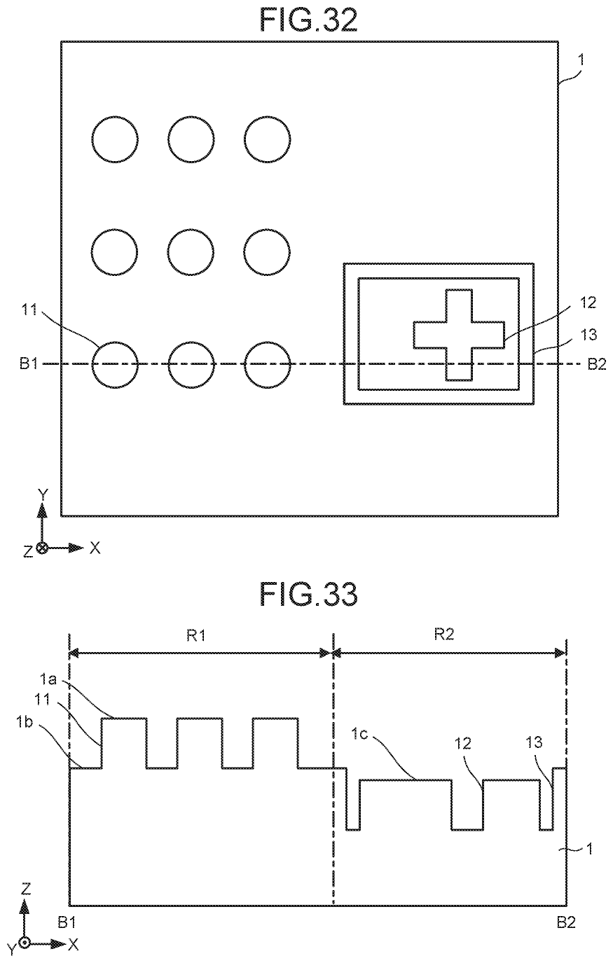

FIG. 32 is an explanatory schematic upper view of still another example of the second substrate processing step S1-4 and illustrates part of the X-Y plane of the substrate 1. FIG. 33 is an explanatory schematic sectional view of the still another example of the second substrate processing step S1-4 and illustrates part of the X-Z cross-section of the substrate 1 along the line B1-B2 in FIG. 32.

The second substrate processing step S1-4 further processes the part of the region R2 while maintaining the shape of the pre-pattern, using the second mask, to form a surface 1c lower than the surface 1b to the first surface 1a, further processes the other part, of the region R2, which includes the groove 12a to form the depression 12, and further processes the still another part, of the region R2, which includes part of the surface 1b to form a depression 13 depressed more than the surface 1c to the surface 1a, to form the alignment mark pattern AM. The second mask is removed after the second substrate processing step S1-4. The surface 1c can surround the depression 12. The other description of the still another example of the second substrate processing step S1-4 can appropriately refer the description of the example of the second substrate processing step S1-4 of the first embodiment.

[Optical Layer Forming Step S2]

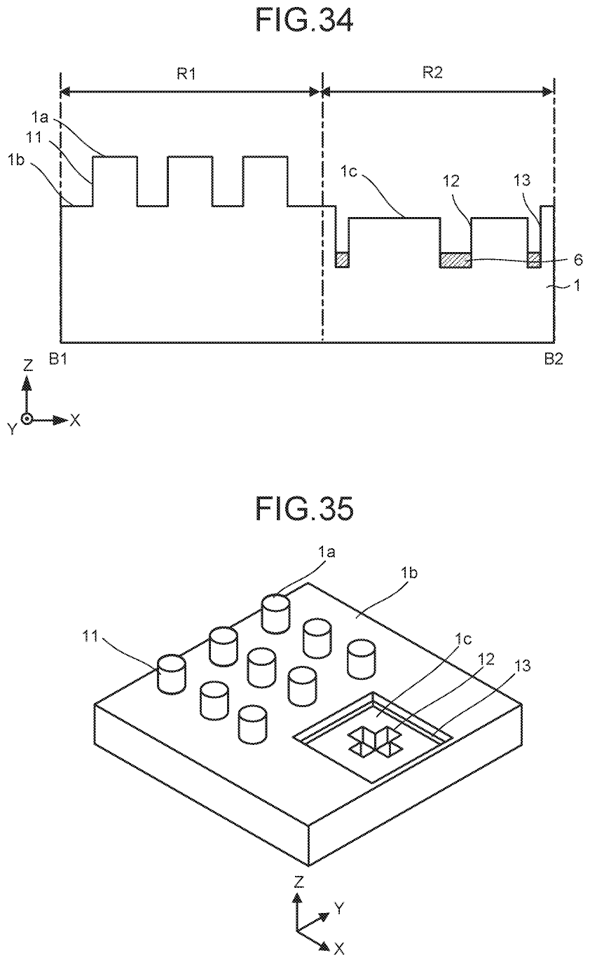

FIG. 34 is an explanatory schematic sectional view of still another example of the optical layer forming step S2 and illustrates part of the X-Z cross-section of the substrate 1 along the line B1-B2. The optical layer forming step S2 forms the optical layer 6 in the depression 12 through the same steps as those of the optical layer forming step S2 of the first embodiment. FIG. 34 illustrates the optical layer 6 in the depression 13, but the optical layer 6 in the depression 13 can be removed by dry etching while a region other than the depression 13 is covered. The other description of the still another example of the optical layer forming step S2 can appropriately refer the description of the example of the optical layer forming step S2 of the first embodiment.

As described above, the example of the method of manufacturing a template of the third embodiment processes the substrate in the plurality of processing steps, to form a first pattern including the protrusions and a second pattern including the depression. This method can enhance the flexibility of the pattern shape. This method can process a substrate having a first surface to form a second surface lower than the first surface, the first pattern including the protrusions protruding more than the second surface, and the second pattern including the depression depressed more than the second surface.

FIG. 35 is an explanatory schematic perspective view of a structure example of the template. FIG. 35 schematically illustrates part of the substrate 1 having the surface 1a, the surface 1b, the surface 1c, the imprint patterns IP each including the protrusions 11, and the alignment mark patterns AM each including the depression 12 and the depression 13.

The example of the method of manufacturing a template of the third embodiment is capable of depressing the depression 12 more than the surface 1c without causing the region around the depression 12 to protrude more than the surface 1a as illustrated in FIG. 35. This can prevent the formation of an unnecessary depression in the imprint material layer formed by NIL. The example of the method of manufacturing a template of the third embodiment also can form the pre-pattern along with the imprint pattern IP, and process the pre-pattern to form the alignment mark pattern AM. This reduces an error in the relative position of the imprint pattern IP and the alignment mark pattern AM.

The example of the method of manufacturing a template of the third embodiment also can form the depression 13 to extend the positional deviation margin of the alignment mark pattern AM in the second substrate processing step S1-4. This can form the alignment mark pattern AM with a lower-cost process.

The third embodiment can be appropriately combined with any of the other embodiments.

### Fourth Embodiment

An example of a method of manufacturing a template of a fourth embodiment includes a pattern forming step S1 and an optical layer forming step S2 similarly to the example of the method of manufacturing a template of the first embodiment. The fourth embodiment details configurations different from those of the first embodiment with omitting the description of configurations as same as those of the first embodiment.

[Pattern Forming Step S1]

The pattern forming step S1 includes a first mask forming step S1-1, a first substrate processing step S1-2, a second mask forming step S1-3, and a second substrate processing step S1-4 as in the first embodiment.

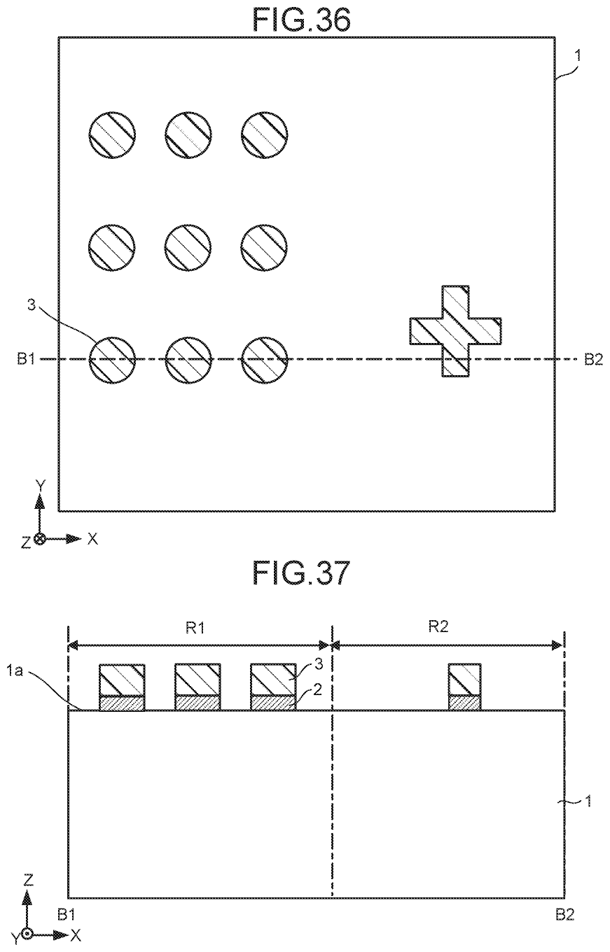

FIG. 36 is an explanatory schematic upper view of still another example of the first mask forming step S1-1 and illustrates part of the X-Y plane of the substrate 1. FIG. 37 is an explanatory schematic sectional view of the still another example of the first mask forming step S1-1 and illustrates part of the X-Z cross-section of the substrate 1 along the line B1-B2 in FIG. 36.

The first mask forming step S1-1 forms a hard mask layer 2 on the surface 1a of the substrate 1, forms a resist mask layer 3 including a pattern on the hard mask layer 2, and processes the hard mask layer 2 using the resist mask layer 3, to form a first mask including the hard mask layer 2 and the resist mask layer 3 and covering the parts of the region R1 and the other part of the region R2 as illustrated in FIGS. 36 and 37. The other description of the still another example of the first mask forming step S1-1 can appropriately refer the description of the example of the first mask forming step S1-1 of the first embodiment.

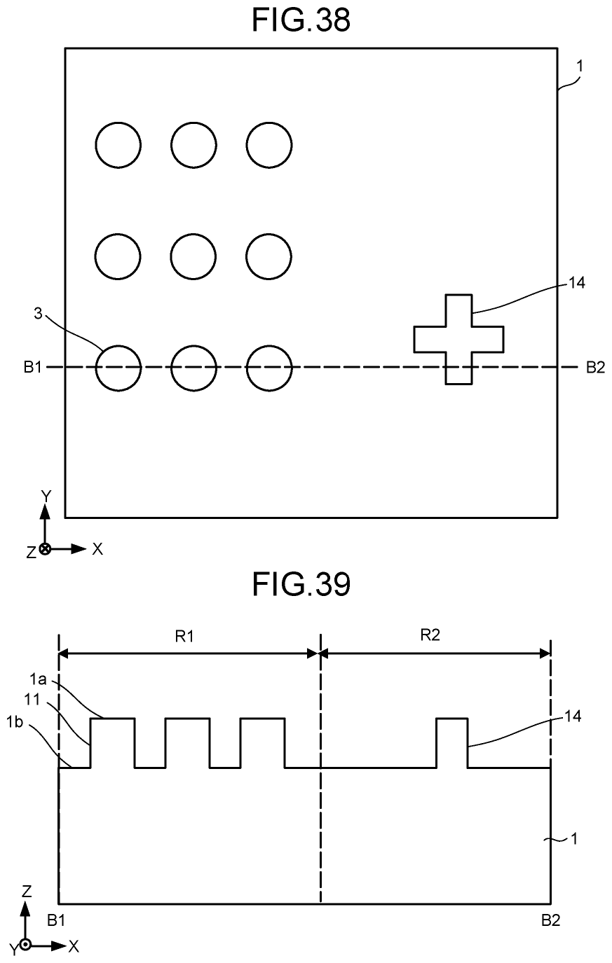

FIG. 38 is an explanatory schematic upper view of still another example of the first substrate processing step S1-2 and illustrates part of the X-Y plane of the substrate 1. FIG. 39 is an explanatory schematic sectional view of the still another example of the first substrate processing step S1-2 and illustrates part of the X-Z cross-section of the substrate 1 along the line B1-B2 in FIG. 38.

The first substrate processing step S1-2 processes the part of the region R2 with the other part of the region R1 using the first mask, to form a pre-pattern including a protrusion 14 protruding more than the surface 1b to the surface 1a, with the surface 1b and the imprint pattern IP. The first mask is removed after the first substrate processing step S1-2.

The protrusion 14 can have an upper surface including another part of the surface 1a. The protrusion 14 can be made from the remainder of the other part of the region R2. The other description of the still another example of the first substrate processing step S1-2 can appropriately refer the description of the example of the first substrate processing step S1-2 of the first embodiment.

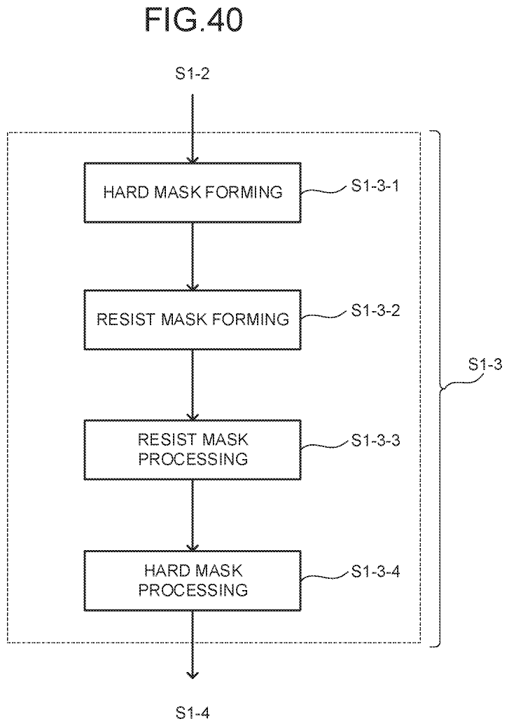

FIG. 40 is an explanatory flowchart of yet another example of the second mask forming step S1-3. The yet another example of the second mask forming step S1-3 includes a hard mask forming step S1-3-1, a resist mask forming step S1-3-2, a resist mask processing step S1-3-3, and a hard mask processing step S1-3-4.

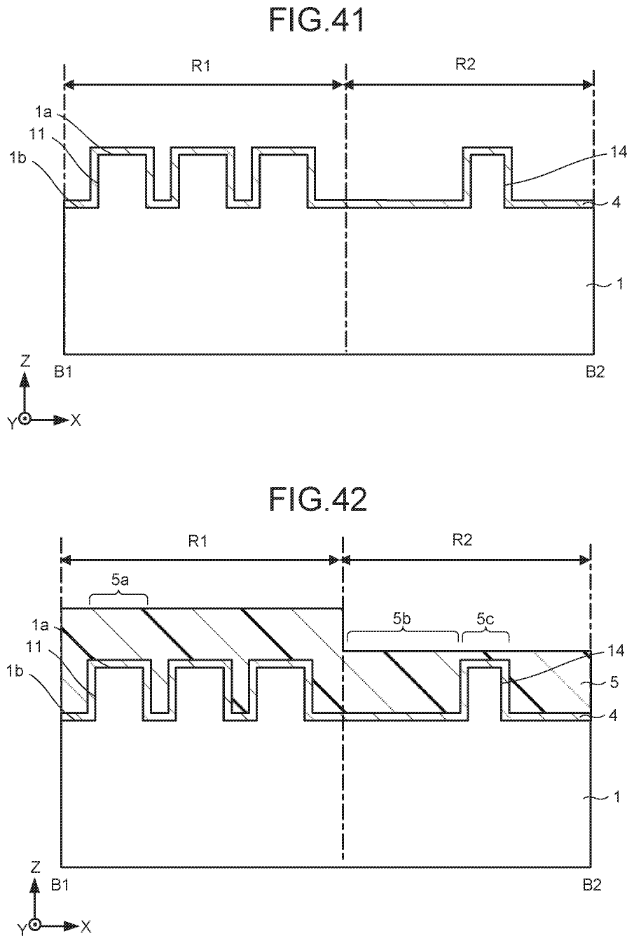

FIG. 41 is an explanatory schematic sectional view of an example of the hard mask forming step S1-3-1 and illustrates part of the X-Z cross-section of the substrate 1 along the line B1-B2.

The hard mask forming step S1-3-1 forms a hard mask layer 4 covering the region R1 and the region R2. The other description of the hard mask layer 4 can appropriately refer the description of the hard mask layer 4 of the first embodiment.

FIG. 42 is an explanatory schematic sectional view of an example of the resist mask forming step S1-3-2 and illustrates part of the X-Z cross-section of the substrate 1 along the line B1-B2.

The resist mask forming step S1-3-2 forms a resist mask layer 5 covering the region R1 and the region R2 on the hard mask layer 4. The resist mask layer 5 includes a portion 5a provided above the protrusions 11, a portion 5b provided above the surface 1b, and a portion 5c provided above the protrusion 14 and thinner than the portion 5a and the portion 5b. The portion 5a to the portion 5c are formed by providing a depression in the resist mask layer 5 above the surface 1b and above the protrusions 14. The other description of the resist mask layer 5 can appropriately refer the description of the resist mask layer 5 of the first embodiment.

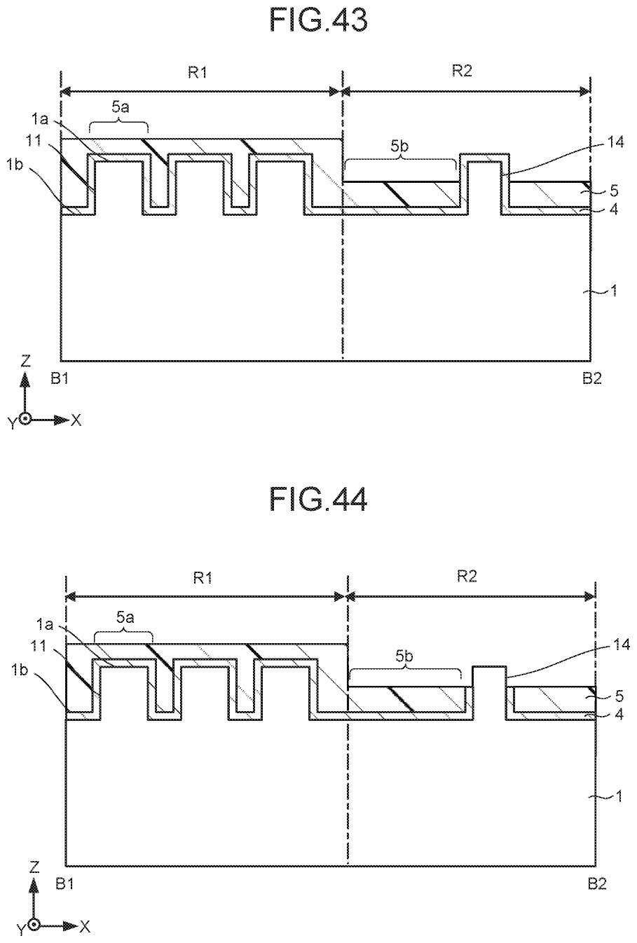

FIG. 43 is an explanatory schematic sectional view of an example of the resist mask processing step S1-3-3 and illustrates part of the X-Z cross-section of the substrate 1 along the line B1-B2.

The resist mask processing step S1-3-3 processes the resist mask layer 5 to remove the portion 5c while partly leaving the portion 5a and the portion 5b, to expose part of the hard mask layer 4. The resist mask layer 5 can be processed by being partly removed along the thickness direction of the substrate 1 using anisotropic etching such as dry etching. Examples of the dry etching include plasma etching using an oxygen gas.

FIG. 44 is an explanatory schematic sectional view of an example of the hard mask processing step S1-3-4 and illustrates part of the X-Z cross-section of the substrate 1 along the line B1-B2.

The hard mask processing step S1-3-4 removes the exposed part of the hard mask layer 4 to expose the surface of part of the protrusion 14, to form a second mask including the remainder of the hard mask layer 4 and the remainder of the resist mask layer 5. The hard mask layer 4 can be processed by being partly removed along the thickness direction of the substrate 1 by anisotropic etching such as dry etching.

After the second mask forming step S1-3, the second substrate processing step S1-4 processes the other part, of the region R2, which includes the protrusion 14 using the second mask until the other part is depressed more than the surface 1b to the surface 1a, to form the depression 12 as in the first embodiment. The other description of yet another example of the substrate processing step S1-4 can appropriately refer the description of the example of the second substrate processing step S1-4 of the first embodiment.

[Optical Layer Forming Step S2]

After the pattern forming step S1, the optical layer forming step S2 forms the optical layer 6 in the depression 12 through the same steps as those of the optical layer forming step S2 of the first embodiment. The other description of yet another example of the optical layer forming step S2 can appropriately refer the description of the example of the optical layer forming step S2 of the first embodiment.

As described above, the example of the method of manufacturing a template of the fourth embodiment processes the substrate in the plurality of processing steps, to form a first pattern including the protrusions and a second pattern including the depression. This method can enhance the flexibility of the pattern shape. This method can process a substrate having a first surface similarly to the example of the method of manufacturing a template of the first embodiment, to form a second surface lower than the first surface, a first pattern including the protrusions protruding more than the second surface, and a second pattern including the depression depressed more than the second surface.

The example of the method of manufacturing a template of the fourth embodiment is capable of depressing the depression 12 more than the surface 1c without causing the region around the depression 12 to protrude more than the surface 1a similarly to the example of the method of manufacturing a template of the first embodiment. This can prevent the formation of an unnecessary depression in the imprint material layer formed by NIL. The example of the method of manufacturing a template of the fourth embodiment also can form the pre-pattern along with the imprint pattern IP, and process the pre-pattern to form the alignment mark pattern AM. This can reduce an error in the relative position of the imprint patterns IP and the alignment mark patterns AM.

The fourth embodiment can be appropriately combined with any of the other embodiments.

### Fifth Embodiment

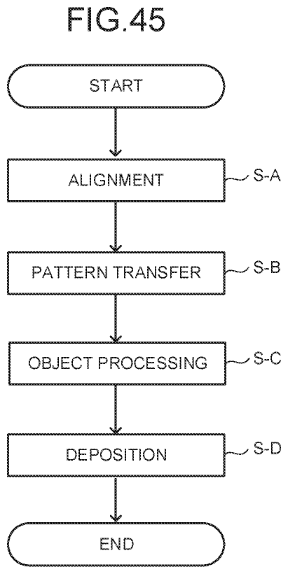

FIG. 45 is an explanatory flowchart of an example of a method of manufacturing a semiconductor device using NIL. The example of the method of manufacturing a semiconductor device includes an alignment step S-A, a pattern transfer step S-B, an object processing step S-C, and a deposition step S-D.

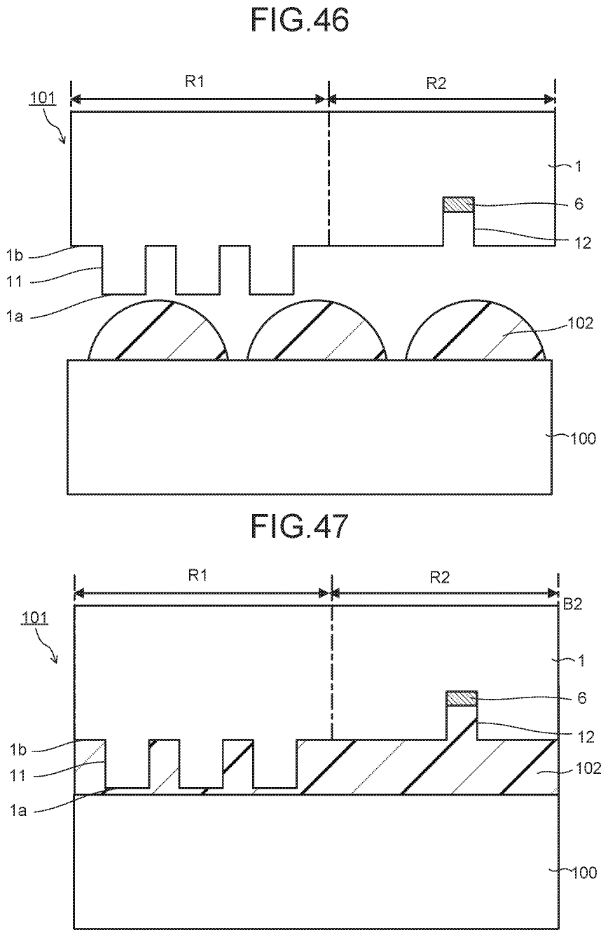

FIG. 46 is an explanatory schematic sectional view of an example of the alignment step S-A. FIG. 46 schematically illustrates an object 100, a template 101, and a layer 102 provided on a processing surface of the object 100. The alignment step S-A aligns the position of the processing surface of the object 100 and the position of a pattern formation surface, of the template 101, which is disposed to face the processing surface. The positions can be aligned by adjusting the relative positions of the alignment mark patterns AM of the template 101 and alignment mark patterns of the object 100.

The object 100 can include a stack of a plurality of films stacked on a semiconductor substrate. The structure of the object 100 is not limited.

The template 101 is the template manufactured by the manufacturing method of one of the first to fourth embodiments. FIG. 46 exemplifies the template 101 manufactured by the method of manufacturing a template of the first embodiment.

The layer 102 is formed by applying an imprint material onto the processing surface before or after the alignment. The imprint material can contain a light curing resin. The imprint material can be applied by dropping or spin coating.

FIG. 47 is an explanatory schematic sectional view of an example of the pattern transfer step S-B. The pattern transfer step S-B presses the template 101 to the layer 102 to shape the layer 102 and cures the shaped layer 102, to transfer the imprint patterns IP and the alignment mark patterns AM to the layer 102. The object 100 and the template 101 can be precisely aligned while the template 101 is pressed to the layer 102 before the layer102 cures. Where each of the imprint patterns IP can have the pillar-shaped protrusions 11, the cured layer 102 has hole patterns as illustrated in FIG. 47.

When the layer 102 contains the light curing resin, the layer 102 is cured by irradiating the layer 102 with light through the template 101. The template 101 is removed from the layer 102 after the layer 102 cures.

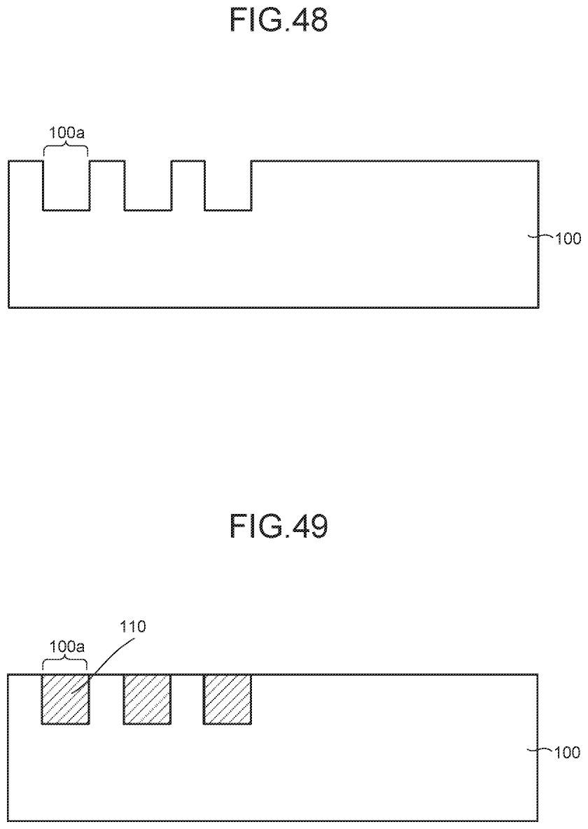

FIG. 48 is an explanatory schematic sectional view of an example of the object processing step S-C. The object processing step S-C can process part of the object 100 using the layer 102, to form openings 100a. The object 100 can be processed by partly removing the stack of the object 100 by dry etching. The shape of the object 100 after it is processed is determined depending on the shapes of the imprint patterns IP and the alignment mark patterns AM.

FIG. 49 is an explanatory schematic sectional view of an example of the deposition step S-D. The deposition step S-D deposits a film on the object 100 and processes the film, to form a layer 110 in the openings 100a. Examples of the layer 110 include a conductive layer containing a metal material. The layer 110 can have a function as embedded wiring.

As described above, the example of the method of manufacturing a semiconductor device of this embodiment shapes the coating layer on the object and transfers the imprint patterns IP and the alignment mark patterns AM using the template manufactured by the manufacturing method of one of the first to fourth embodiments. This can transfer the imprint patterns IP and the alignment mark patterns AM without forming unnecessary depressions around the alignment mark patterns AM. This can manufacture the semiconductor device without forming an unnecessary metal layer, resulting in preventing the performance deterioration of the semiconductor device.

While certain embodiments of the present invention have been described, these embodiments have been presented by way of example only, and are not intended to limit the scope of the inventions. The novel embodiments described herein can be embodied in a variety of other forms; furthermore, various omissions, substitutions and changes can be made therein without departing from the spirit of the inventions. The accompanying claims and their equivalents are intended to cover such forms or modifications as would fall within the scope and spirit of the inventions.

What is claimed is:

1. A method of manufacturing a template, comprising:
covering a part of a first region of a substrate;
processing another part of the first region to form a first pattern including a protrusion;
covering the first region; and
processing at least part of a second region of the substrate to form a second pattern including a depression.

2. The method according to claim 1, wherein:
the first and second regions face a first surface of the substrate before the first pattern is formed;
the part of the first region is covered with a first mask before the first pattern is formed;
the first pattern is formed with a second surface lower than the first surface by processing the other part of the first region using the first mask;
the protrusion protrudes more than the second surface to the first surface;
the second region before the second pattern being formed faces the first surface or the second surface;
the first region is covered with a second mask before the second pattern is formed;
the second pattern is formed by processing the at least part of the second region using the second mask; and
the depression is depressed more than the second surface to the first surface.

3. The method according to claim 2, wherein:
the first mask further covers a part of the second region; and
the second pattern is formed by
processing another part of the second region with the other part of the first region using the first mask to form a pre-pattern including a groove depressed from the first surface, with the second surface and the first pattern, and
further processing the part of the second region using the second mask while maintaining a shape of the pre-pattern to form a third surface lower than the second surface to the first surface, and further processing the groove with the other part of the second region to form the depression.

4. The method according to claim 2, wherein:
the first mask further covers a part of the second region; and
the second pattern is formed by
processing a part of a region between another part of the second region and the first region with the other part of the first region and the other part of the second region, using the first mask, to form a pre-pattern including a groove depressed from the first surface, with the second surface and the first pattern, and
further processing the part of the second region while maintaining a shape of the pre-pattern, using the second mask, to form a third surface lower than the second surface to the first surface, further processing the groove with the other part of the second region to form the depression, and further processing the part of the region between the other part of the second region and the first region to form a second depression depressed more than the third surface to the first surface.

5. The method according to claim 2, wherein:
the first mask further covers a part of the second region; and
the second pattern is formed by:
processing the other part of the first region using the first mask to form the second surface and the first pattern, and processing another part of the second region to form a pre-pattern including a second protrusion protruding more than the second surface to the first surface;
forming a first mask layer covering the first region and the second region;
forming a second mask layer on the first mask layer, the second mask layer including a first portion above the protrusion, a second portion above the second surface, and a third portion above the second protrusion and thinner than the first and second portions;
removing the third portion while the first and second portions partly remaining, to expose a part of the first mask layer;
removing the exposed part of the first mask layer to expose a part of the second protrusion, to form the second mask including the remainder of the first mask layer and the remainder of the second mask layer; and
processing the second protrusion with the part of the second region using the second mask to form the depression.

6. The method according to claim 1, further comprising forming an optical layer in the depression.

7. The method according to claim 6, wherein the optical layer contains at least one material selected from the group consisting of titanium, tantalum, tungsten, chromium, copper, silicon carbide, and silicon fluoride.

8. The method according to claim 1, wherein the second pattern is a pattern of an alignment mark.

9. A template comprising:
a substrate including
a first surface,
a second surface lower than the first surface,
a first pattern having a protrusion protruding more than the second surface to the first surface, and
a second pattern having a depression depressed more than the second surface to the first surface; and
an optical layer in the depression.

10. The template according to claim 9, wherein the optical layer contains at least one material selected from the group consisting of titanium, tantalum, tungsten, chromium, copper, silicon carbide, and silicon fluoride.

11. The template according to claim 9, wherein the second pattern is a pattern of an alignment mark.

12. The template according to claim 9, wherein the second pattern further includes a second depression between the first pattern and the depression and depressed more than the second surface to the first surface.

13. A method of manufacturing a semiconductor device, comprising:
aligning a position of a processing surface of an object and a position of a pattern formation surface of the template according to claim 9, the pattern formation surface being disposed to face the processing surface; and
pressing the template to a layer formed of an imprint material applied on the processing surface, to shape the layer, and curing the shaped layer to transfer the first pattern and the second pattern to the layer.
